(19) United States
(12) Patent Application Publication
(10) Pub. No.: US 2024/0128375 A1
(43) Pub. Date: Apr. 18, 2024

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Chun-Yi CHANG, Taoyuan City (TW); Yu Ying CHEN, Taoyuan City (TW); Zhen-Cheng WU, Hsinchu City (TW); Chi On CHUI, Hsinchu City (TW)

(73) Assignee: TAIWAN SEMICONDUCTOR MANUFACTURING COMPANY, LTD., Hsinchu (TW)

(21) Appl. No.: 18/184,666

(22) Filed: Mar. 16, 2023

Related U.S. Application Data
(60) Provisional application No. 63/415,581, filed on Oct. 12, 2022.

(51) Int. Cl. H01L 29/78; H01L 21/8234; H01L 27/088; H01L 29/66

(52) U.S. Cl. CPC H01L 29/7851; H01L 21/823418; H01L 21/823431; H01L 27/0886; H01L 29/66545; H01L 29/66795

(57) ABSTRACT

A method includes forming first and second semiconductor fins and a gate structure over a substrate; forming a first and second source/drain epitaxy structures over the first and second semiconductor fins; forming an interlayer dielectric (ILD) layer over the first and second source/drain epitaxy structures; etching the gate structure and the ILD layer to form a trench; performing a first surface treatment to modify surfaces of a top portion and a bottom portion of the trench to NH-terminated; performing a second surface treatment to modify the surfaces of the top portion of the trench to N-terminated, while leaving the surfaces of the bottom portion of the trench being NH-terminated; and depositing a first dielectric layer in the trench, wherein the first dielectric layer has a higher deposition rate on the surfaces of the bottom portion of the trench than on the surfaces of the bottom portion of the trench.

### PRIORITY CLAIM AND CROSS-REFERENCE

The present application claims priority to U.S. Provisional Application Ser. No. 63/415,581, filed Oct. 12, 2022, which is herein incorporated by reference.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 12C illustrate a method for manufacturing a semiconductor device at various stages in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

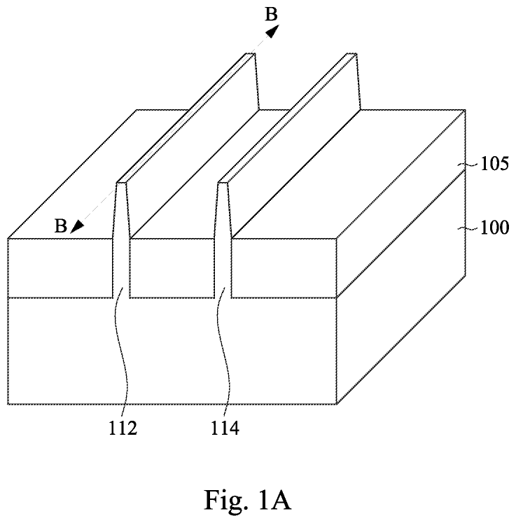

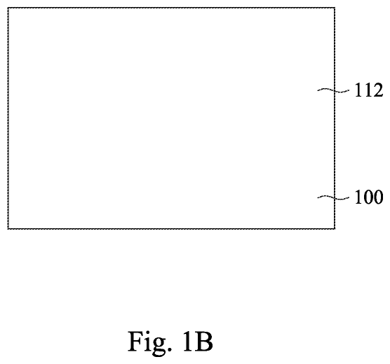

FIGS. 1A to 12C illustrate a method for manufacturing a semiconductor device at various stages in accordance with some embodiments of the present disclosure. Although the views shown in FIGS. 1A to 12C are described with reference to a method, it will be appreciated that the structures shown in FIGS. 1A to 12C are not limited to the method but rather may stand alone separate of the method. Although FIGS. 1A to 12C are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

Reference is made to FIGS. 1A and 1B, in which FIG. 1B is a cross-sectional view along line B-B of FIG. 1A. Shown there is a substrate 100. The substrate 100 may be a semiconductor substrate, such as a bulk semiconductor, a semiconductor-on-insulator (SOI) substrate, or the like. The substrate 100 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Semiconductor fins 112 and 114 are formed over the substrate 100. The semiconductor fins 112 and 114 may be formed by, for example, forming a mask layer over the substrate 100, the mask layer including openings that expose portions of the substrate 100. The exposed substrate 100 is then etched through the openings of the mask layer, forming trenches in the substrate 100. A portion of the substrate 100 between neighboring trenches can be referred to as the semiconductor fin.

Isolation structures 105 may be formed over the substrate 100 and laterally surrounding bottom portions of the semiconductor fins 112 and 114. The isolation structures 105 can be referred to as shallow trench isolation (STI) structures. The isolation structures 105 can be formed by, for example depositing a dielectric material blanket over the substrate 100 and overfilling the spaces between the semiconductor fins 112 and 114, performing a planarization process such as chemical mechanical polish (CMP) to remove excess dielectric material until the top surfaces of the semiconductor fins 112 and 114 are exposed. Afterward, the dielectric material is recessed, for example, through an etching operation, in which diluted HF, SiCoNi (including HF and NH 3), or the like, may be used as the etchant. After recessing the isolation structures 105, top portions of the semiconductor fins 112 and 114 are higher than the top surfaces of the isolation structures 105, and hence top portions of the semiconductor fins 112 and 114 protrude above the isolation structures 105.

In some embodiments, the isolation structures 105 are made of silicon oxide, silicon nitride, silicon oxynitride, fluoride-doped silicate glass (FSG), or other low-K dielectric materials. In some embodiments, the isolation structures 105 may be formed using a high-density-plasma (HDP) chemical vapor deposition (CVD) process, using silane (SiH₄) and oxygen (O₂) as reacting precursors. In some other embodiments, the isolation structures 105 may be formed using a sub-atmospheric CVD (SACVD) process or high aspect-ratio process (HARP), in which process gases may include tetraethylorthosilicate (TEOS) and ozone (O₃). In yet other embodiments, the isolation structures 105 may be formed using a spin-on-dielectric (SOD) process, such as hydrogen silsesquioxane (HSQ) or methyl silsesquioxane (MSQ). Other processes and materials may be used. In some embodiments, the isolation structures 105 can have a multi-layer structure, for example, a thermal oxide liner layer with silicon nitride formed over the liner. Thereafter, a thermal annealing may be optionally performed to the isolation structures 105.

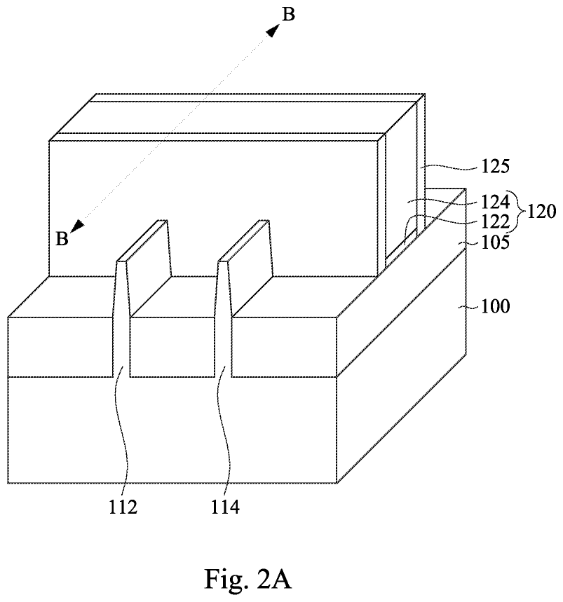

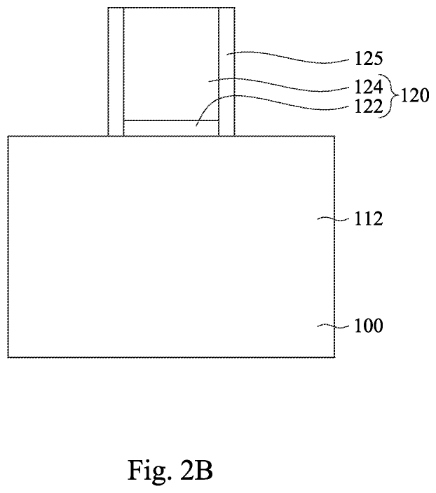

Reference is made to FIGS. 2A and 2B, in which FIG. 2B is a cross-sectional view along line B-B of FIG. 2A. Dummy gate structure 120 is formed over the substrate 100 and crossing the semiconductor fins 112 and 114. In some embodiments, the dummy gate structure 120 includes a gate dielectric layer 122 and a gate electrode 124 over the gate dielectric layer 122. The dummy gate structure 120 may be formed by, for example, depositing a gate dielectric material blanket over the substrate 100, depositing a gate electrode material over the gate dielectric material, and then patterning the gate dielectric material and the gate electrode material.

In some embodiments, the gate dielectric layer 122 is an oxide layer, such as silicon oxide. In some embodiments, the gate dielectric layer 122 is made of high-k dielectric materials, such as metal oxides, transition metal-oxides, or the like. Examples of the high-k dielectric material include, but are not limited to, hafnium oxide (HfO₂), hafnium silicon oxide (HfSiO), hafnium tantalum oxide (HfTaO), hafnium titanium oxide (HfTiO), hafnium zirconium oxide (HfZrO), zirconium oxide, titanium oxide, aluminum oxide, hafnium dioxide-alumina (HfO₂—Al₂O₃) alloy, or other applicable dielectric materials. The gate dielectric layer 122 may be formed by a deposition processes, such as chemical vapor deposition (CVD), physical vapor deposition (PVD), atomic layer deposition (ALD), plasma enhanced CVD (PECVD) or other suitable techniques.

In some embodiments, the gate electrode 124 may include polycrystalline-silicon (poly-Si), poly-crystalline silicon-germanium (poly-SiGe), metallic nitrides, metallic silicides, metallic oxides, or metals. In some embodiments, the gate electrode 124 includes a metal-containing material such as TiN, TaN, TaC, Co, Ru, Al, combinations thereof, or multi-layers thereof. The gate electrode 124 may be deposited by CVD, physical vapor deposition (PVD), sputter deposition, or other techniques suitable for depositing conductive materials.

Gate spacers 125 are formed on opposite sidewalls of the dummy gate structure 120. The method of forming the gate spacers 125 includes blanket forming a dielectric layer over the substrate 100 using, for example, CVD, PVD or ALD, and then performing an etching process such as anisotropic etching to remove horizontal portions of the dielectric layer. The remaining portions of the dielectric layer on sidewalls of the dummy gate structure 120 can serve as the gate spacers 125. In some embodiments, the gate spacers 125 may be used to offset subsequently formed source/drain regions. The gate spacers 125 may further be used for designing or modifying the source/drain region profile. In some embodiments, the gate spacers 125 may include silicon oxide, silicon nitride, silicon oxynitride, silicon carbide, silicon carbonitride, silicon oxycarbonitride, silicon oxycarbide, porous dielectric materials, hydrogen doped silicon oxycarbide (SiOC:H), low-k dielectric materials or other suitable dielectric material. The gate spacers 125 may include a single layer or multilayer structure made of different dielectric materials.

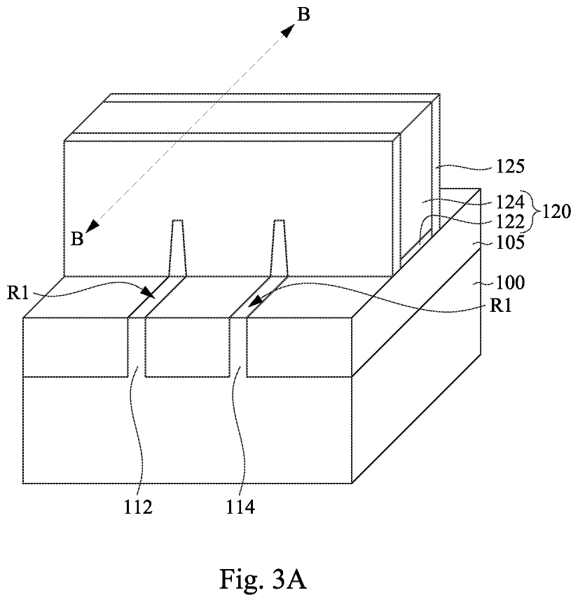

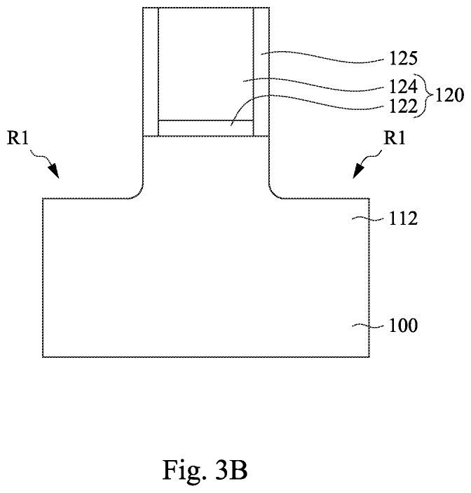

Reference is made to FIGS. 3A and 3B, in which FIG. 3B is a cross-sectional view along line B-B of FIG. 3A. Portions of the semiconductor fins 112 and 114 exposed by the dummy gate structures 120 and the gate spacers 125 are partially removed (or partially recessed) to form recesses R1. On the other hand, portions of the semiconductor fins 112 and 114 under the dummy gate structures 120 may act as channel regions of transistors.

Formation of the recesses R1 may include a dry etching process, a wet etching process, or combination dry and wet etching processes. This etching process may include reactive ion etch (RIE) using the dummy gate structure 120 and gate spacers 125 as masks, or by any other suitable removal process. After the etching process, a pre-cleaning process may be performed to clean the recesses R1 with hydrofluoric acid (HF) or other suitable solution in some embodiments.

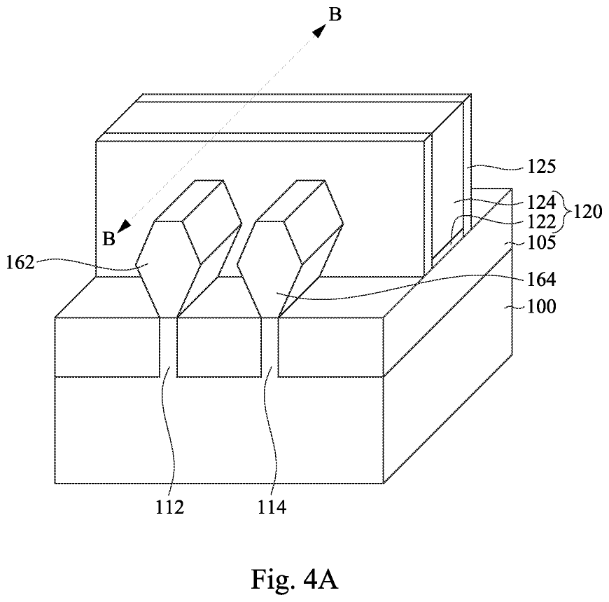

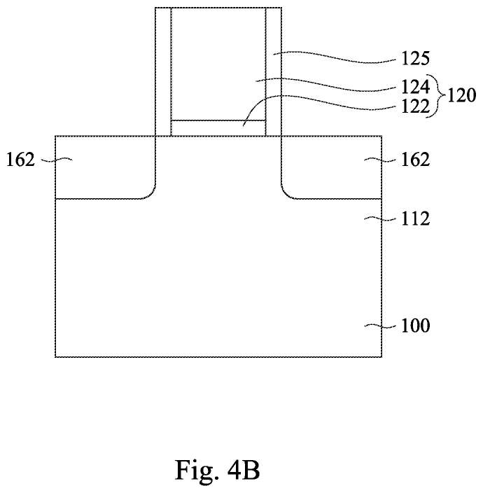

Reference is made to FIGS. 4A and 4B, in which FIG. 4B is a cross-sectional view along line B-B of FIG. 4A. Epitaxial source/drain structures 162 and 164 are formed in the recesses R1 of the semiconductor fins 112 and 114, respectively. In greater details, as shown in the cross-sectional view of FIG. 4B, the epitaxial source/drain structures 162 are formed on opposite sides of the gate structure 120. Although not shown, the epitaxial source/drain structures 164 are formed on opposite sides of the gate structure 120 as well. It is noted that, source/drain region(s) may refer to a source or a drain, individually or collectively dependent upon the context.

The epitaxial source/drain structures 162 and 164 may be formed using one or more epitaxy or epitaxial (epi) processes, such that Si features, SiGe features, silicon phosphate (SiP) features, silicon carbide (SiC) features and/or other suitable features can be formed in a crystalline state on the recessed portions of the semiconductor fins 112 and 114. In some embodiments, lattice constants of the epitaxial source/drain structures 162 and 164 are different from that of the semiconductor fins 112 and 114, so that the channel region between the epitaxial source/drain structures 162 and 164 can be strained or stressed by the epitaxial source/drain structures 162 and 164 to improve carrier mobility of the semiconductor device and enhance the device performance.

The epitaxy processes include CVD deposition techniques (e.g., vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor fins 112 and 114 (e.g., silicon, silicon germanium, silicon phosphate, or the like). The epitaxial source/drain structures 162 and 164 may be in-situ doped. The doping species include p-type dopants, such as boron or BF₂; n-type dopants, such as phosphorus or arsenic; and/or other suitable dopants including combinations thereof. If the epitaxial source/drain structures 162 and 164 are not in-situ doped, a second implantation process (i.e., a junction implant process) is performed to dope the epitaxial source/drain structures 162 and 164. One or more annealing processes may be performed to activate the epitaxial source/drain structures 162 and 164. The annealing processes include rapid thermal annealing (RTA) and/or laser annealing processes.

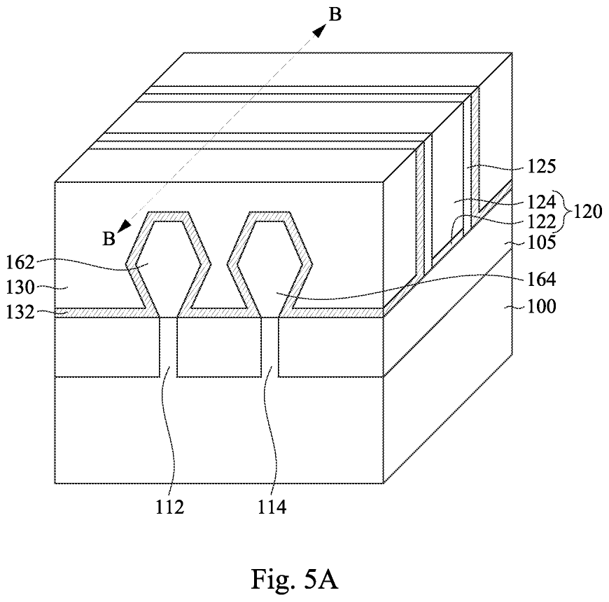

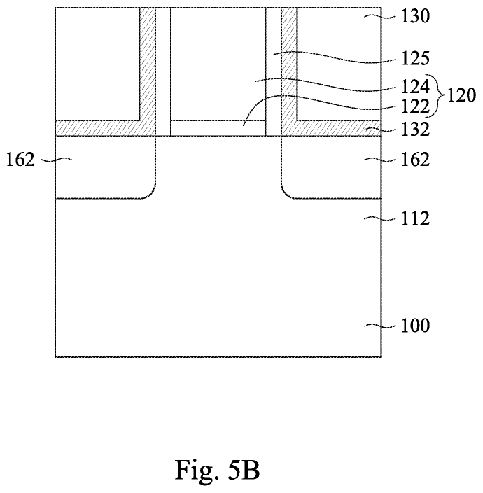

Reference is made to FIGS. 5A and 5B, in which FIG. 5B is a cross-sectional view along line B-B of FIG. 5A. A contact etch stop layer (CESL) 132 is blanket formed on the structure shown in FIGS. 4A and 4B, and then, an interlayer dielectric (ILD) layer 130 is formed over the CESL 132. Afterwards, a CMP process may be optionally performed to remove excess materials of the ILD layer 130 and the CESL 132 to expose the dummy gate structure 120. The CMP process may planarize a top surface of the ILD layer 130 with top surfaces of the dummy gate structure 120, gate spacers 125, and the CESL 132 in some embodiments.

The CESL 132 may be a dielectric layer including silicon nitride, silicon oxynitride or other suitable materials. The CESL 132 can be formed using, for example, plasma enhanced CVD, low pressure CVD, ALD or other suitable techniques. The ILD layer 130 may include a material different from the CESL 132. In some embodiments, the ILD layer 130 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD layer 130 may be formed using, for example, CVD, ALD, spin-on-glass (SOG) or other suitable techniques.

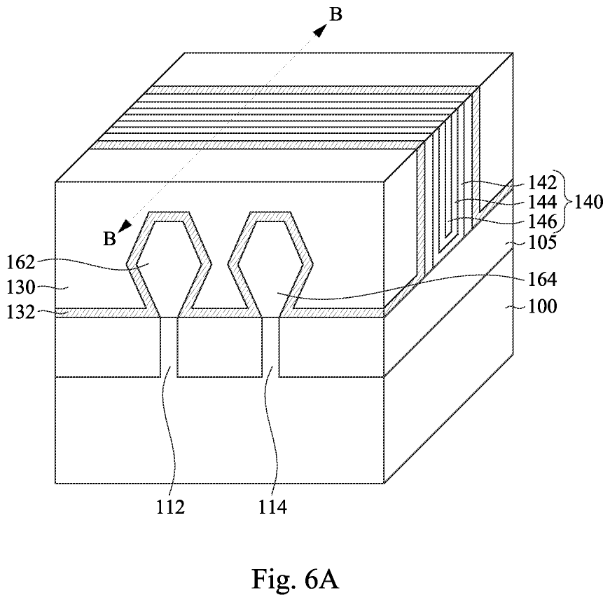

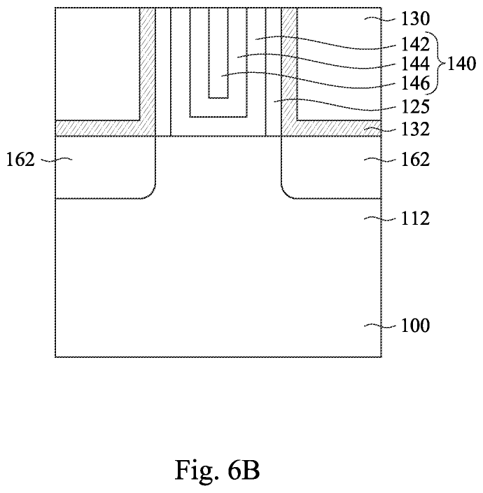

Reference is made to FIGS. 6A and 6B, in which FIG. 6B is a cross-sectional view along line B-B of FIG. 6A. The dummy gate structure 120 is replaced with a metal gate structure 140. In some embodiments using a gate-last process, the dummy gate structure 120 may be removed to form gate trenches within the gate spacers 125. A plurality of layers included in the metal gate structure 140 may be sequentially deposited in the gate trenches. Then, a CMP process is performed to remove excessive materials to form the metal gate structure 140. In some embodiments, each of the metal gate structures 140 may include a gate dielectric layer 142, a work function metal layer 144, and a gate electrode 146.

In some embodiments, the gate dielectric layer 142 may include one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. The gate dielectric layer 142 may be formed by CVD, ALD or any suitable method.

In some embodiments, the work function metal layer 144 may be made of a conductive material such as a single layer of TiN, TaN, TaAlC, TiC, TaC, Co, Al, TiAl, HfTi, TiSi, TaSi or TiAlC, or a multilayer of two or more of these materials. For the n-channel FET, one or more of TaN, TaAlC, TiN, TiC, Co, TiAl, HfTi, TiSi and TaSi is used as the work function metal layer 144, and for the p-channel FET, one or more of TiAlC, Al, TiAl, TaN, TaAlC, TiN, TiC and Co is used as the work function metal layer 144. The work function metal layer 144 may be formed by ALD, PVD, CVD, e-beam evaporation, or other suitable process.

In some embodiments, the gate electrode 146 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode 146 may be formed by CVD, ALD, electro-plating, or other suitable method.

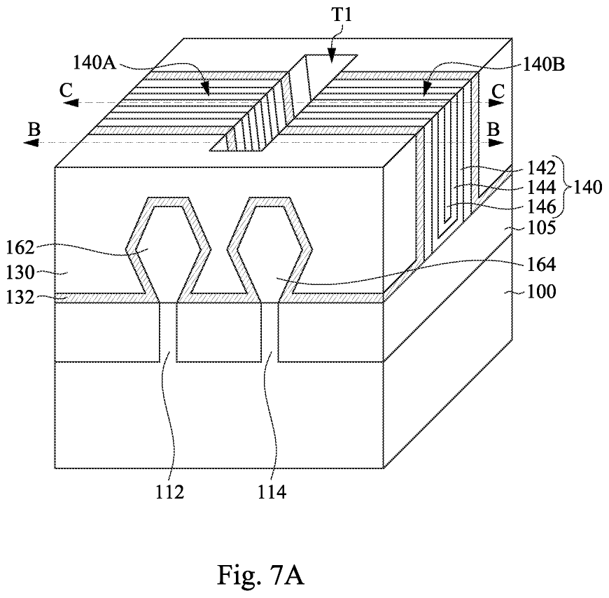

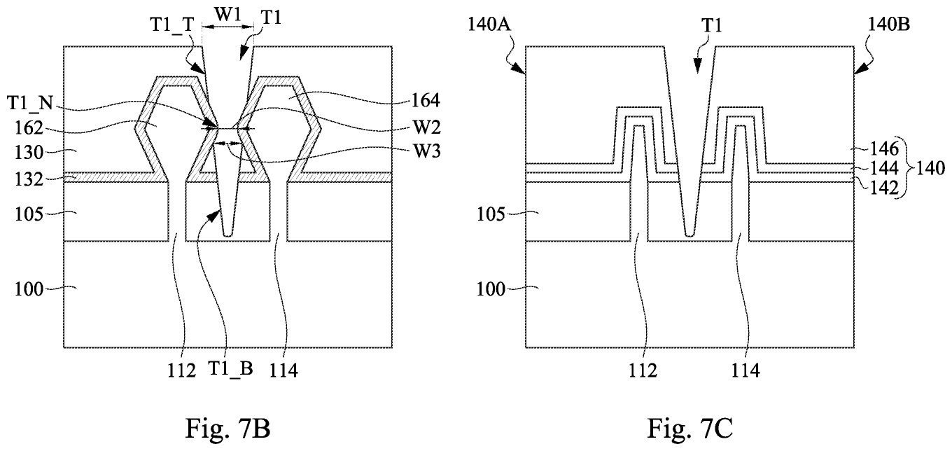

Reference is made to FIGS. 7A to 7C, in which FIG. 7B is a cross-sectional view along line B-B of FIG. 7A, and FIG. 7C is a cross-sectional view along line C-C of FIG. 7A. Here, the cross-sectional view of FIG. 7B is taken along the epitaxial source/drain structures 162 and 164, and is perpendicular to the lengthwise direction of semiconductor fins 112 and 114. On the other hand, the cross-sectional view of FIG. 7C is taken along the gate structure 140, and is perpendicular to the lengthwise direction of semiconductor fins 112 and 114.

An etching process is performed to the structure shown in FIGS. 6A and 6B, so as to form a trench T1 extending from top surfaces of the gate structure 140 and the ILD layer 130 to the isolation structures 105. In some embodiments, the etching process may be performed by, for example, forming a patterned mask (e.g., a photoresist) over the structure shown in FIGS. 6A and 6B, performing an etching process by using the patterned mask as an etch mask to remove unwanted portions of the structure shown in FIGS. 6A and 6B, and then removing the patterned mask. As a result of the etching process, the gate structure 140 is divided (or broken) into separated portions 140A and 140B. In some embodiments, the portions 140A and 140B can also be referred to as gate structures 140A and 140B.

With respect to the cross-sectional view of FIG. 7B, the trench T1 in FIG. 7B has a bowling-shape cross-sectional profile. For example, the trench T1 may include a top portion T1_T and a bottom portion T1_B below the top portion T1_T, in which the top portion T1_T and the bottom portion T1_B are separated by a neck portion T1_N. Here, the neck portion T1_N has a maximal width that is less than the maximal width of the top portion T1_T and the maximal width of the bottom portion T1_B. This is because the CESL 132 may act as an etch stop layer during the patterning process, the etching process of the patterning process may include a higher etching rate on the ILD layer 130 and the isolation structures 105 than on the CESL 132.

In greater details, with respect to the top portion T1_T of the trench T1, the top end of the top portion T1_T has a width W1. The width of the top portion T1_T may decrease toward the neck portion T1_N, which includes a width W2. That is, the width of the top portion T1_T may continuously decrease from the width W1 to the width W2. Then, with respect to the bottom portion T1_B of the trench T1, the width of the bottom portion T1_B may continuously increase from the width W2 to a width W3, and may continuously decrease from the width W3 to the bottom end of the bottom portion T1_B of the trench T1. In some embodiments, the width W2 is less than the widths W1 and W3, in which the width W1 is the maximal width of the top portion T1_T, and the width W3 is the maximal width of the bottom portion T1_B. In some embodiments, the width W3 is less than the width W1.

Here, the neck portion T1_N of the trench T1 is substantially level to the widest portions of the epitaxial source/drain structures 162 and 164. Stated another way, the neck portion T1_N of the trench T1 is substantially level to a position where the closest distance between the epitaxial source/drain structures 162 and 164 occurs. Sated another way, the top portion T1_T of the trench T1 can be referred to as the portion of the trench T1 above the widest portions of the epitaxial source/drain structures 162 and 164, and the bottom portion T1_B of the trench T1 can be referred to as the portion of the trench T1 below the widest portions of the epitaxial source/drain structures 162 and 164.

With respect to the cross-sectional view of FIG. 7C, the trench T1 in FIG. 7C has a V-shape cross-sectional profile. That is, the width of the trench T1 in the cross-sectional view of FIG. 7C may continuously decrease from the top end of the trench T1 toward the bottom end of the trench T1. In some embodiments, the width variation of the trench T1 in the cross-sectional view of FIG. 7B is greater than the width variation of the trench T1 in the cross-sectional view of FIG. 7C. This is because, in the cross-sectional view of FIG. 7C, there is no strong etch stop material (e.g., the CESL 132) during the patterning process.

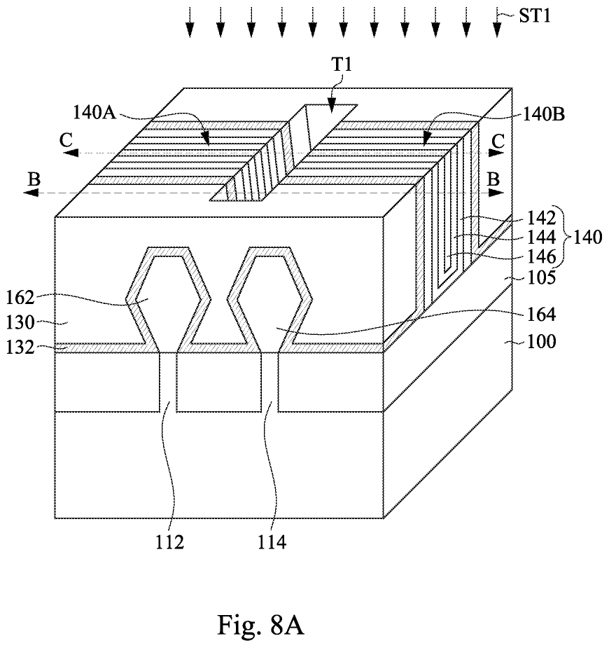

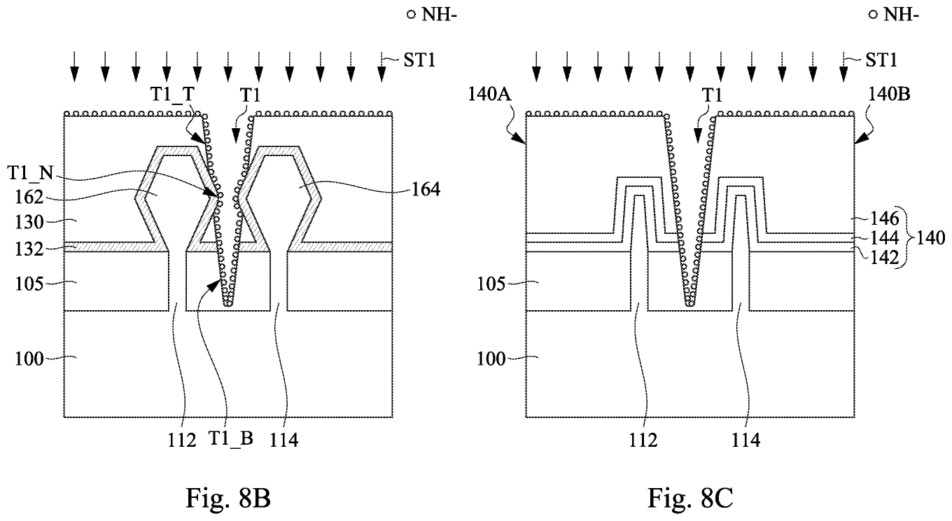

Reference is made to FIGS. 8A to 8C, in which FIG. 8B is a cross-sectional view along line B-B of FIG. 8A, and FIG. 8C is a cross-sectional view along line C-C of FIG. 8A. A first surface treatment ST1 is performed to the structure shown in FIGS. 7A to 7C, so as to modify the exposed surfaces of the structure shown in FIGS. 7A to 7C to be NH-terminated. In greater details, the exposed surfaces of the ILD layer 130, the CESL 132, the gate structure 140, the isolation structure 105 are modified to NH-terminated. In some embodiments, the first surface treatment ST1 can be referred to as a pre-treatment process.

In some embodiments, the first surface treatment ST1 is performed by supplying nitrogen-containing gas and hydrogen-containing gas over the substrate 100 with plasma treatment. The nitrogen-containing gas may be N₂. The hydrogen-containing gas may be H₂. In some embodiments, the flow rate of the N₂ gas is in a range from about 100 sccm to about 100000 sccm, and the flow rate of the H₂ gas is in a range from about 10 sccm to about 10000 sccm. In some embodiments, the first surface treatment ST1 is performed under a pressure in a range from about 0.1 torr to about 100 torr. In some embodiments, the first surface treatment ST1 is performed with an RF power in a range from about 10 W to about 1000 W. In some embodiments, the duration of the first surface treatment ST1 is in a range from about 0.1 s to about 1000 s.

In some embodiments, the flow rates of the nitrogen-containing gas and the hydrogen-containing gas, the pressure of the first surface treatment ST1, the RF power, and the duration of the first surface treatment ST1 may be tuned such that the NH-termination species may be spread into the bottom of the trench T1, such that an entirety of the surfaces of the trench T1 is modified to NH-terminated.

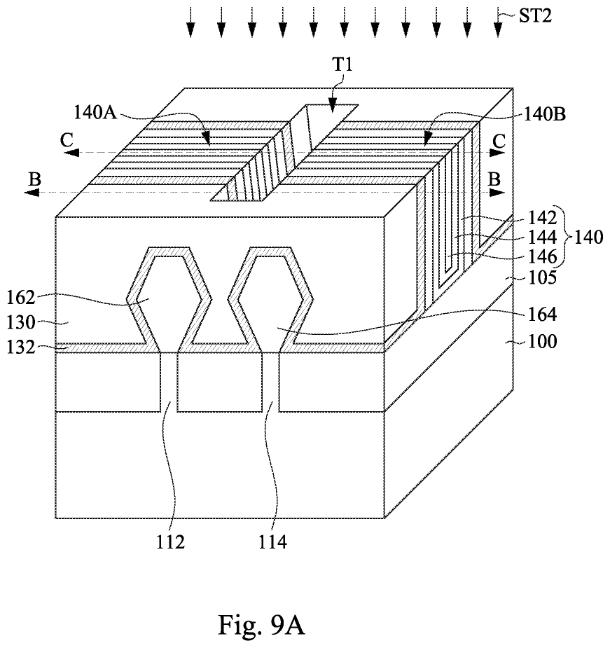

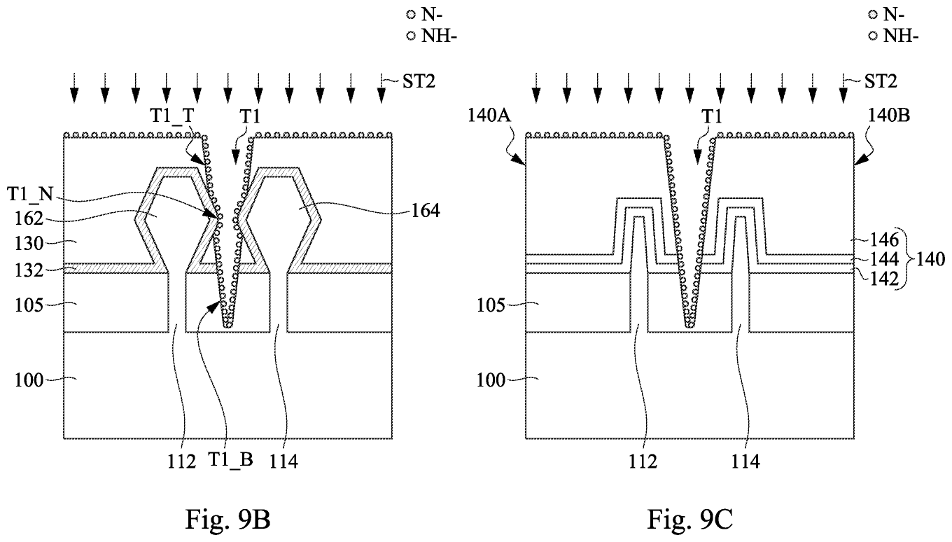

Reference is made to FIGS. 9A to 9C, in which FIG. 9B is a cross-sectional view along line B-B of FIG. 9A, and FIG. 9C is a cross-sectional view along line C-C of FIG. 9A. A second surface treatment ST2 is performed to the structure shown in FIGS. 8A to 8C, so as to modify the top surfaces of the ILD layer 130, the gate structure 140, and the surfaces of the top portion T1_T of the trench T1 to be N-terminated. In some embodiments, the first surface treatment ST1 and the second surface treatment ST2 can be collectively referred to as a surface modification process.

In some embodiments, the second surface treatment ST2 is performed by supplying nitrogen-containing gas over the substrate 100 with plasma treatment. The nitrogen-containing gas may be N₂. In some embodiments, the flow rate of the N₂ gas is in a range from about 100 sccm to about 100000 sccm. In some embodiments, the second surface treatment ST2 is performed under a pressure in a range from about 0.1 torr to about 100 torr. In some embodiments, the second surface treatment ST2 is performed with an RF power in a range from about 10 W to about 1000 W. In some embodiments, the duration of the second surface treatment ST2 is in a range from about 0.1 s to about 1000 s. In some embodiments, the second surface treatment ST2 is performed without using hydrogen-containing gas, such as H₂.

In some embodiments, the flow rates of the nitrogen-containing gas, the pressure of the second surface treatment ST2, the RF power, and the duration of the second surface treatment ST2 may be tuned such that the NH-termination species at the top surfaces of the ILD layer 130, the gate structure 140, and the surfaces of the top portion T1_T of the trench T1 are replaced with N-termination species. However, the process condition is also tuned such that the N-termination species may not reach the bottom portion T1_B of the trench T1, so as to keep the surfaces of the bottom portion T1_B of the trench T1 being NH-terminated after the second surface treatment ST2 is completed.

In some embodiments, the pressure of the first surface treatment ST1 is lower than the pressure of the second surface treatment ST2. The duration of the first surface treatment ST1 is longer than the duration of the second surface treatment ST2. This will ensure that the surfaces of the bottom portion T1_B of the trench T1 being NH-terminated after the second surface treatment ST2 is completed.

After the second surface treatment ST2 is completed, the top surfaces of the ILD layer 130 and the gate structure 140, and the surfaces of the top portion T1_T of the trench T1 have more N-termination species than the bottom portion T1_B of the trench T1. In other words, the bottom portion T1_B of the trench T1 has more NH-termination species than the top surfaces of the ILD layer 130 and the gate structure 140, and the surfaces of the top portion T1_T of the trench T1. In some embodiments, the exposed surfaces of the ILD layer 130, the CESL 132, and the gate structure 140 have more N-termination species than the exposed surfaces of the isolation structures 105. In other words, the exposed surfaces of the isolation structures 105 have more NH-termination species than the exposed surfaces of the ILD layer 130, the CESL 132, and the gate structure 140.

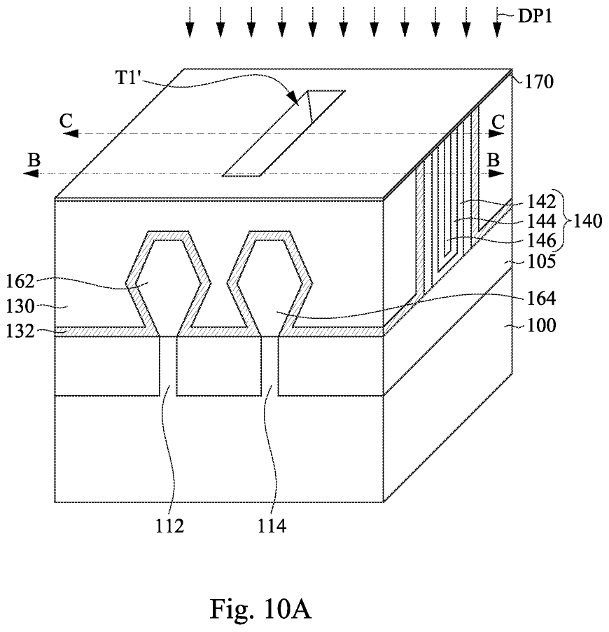

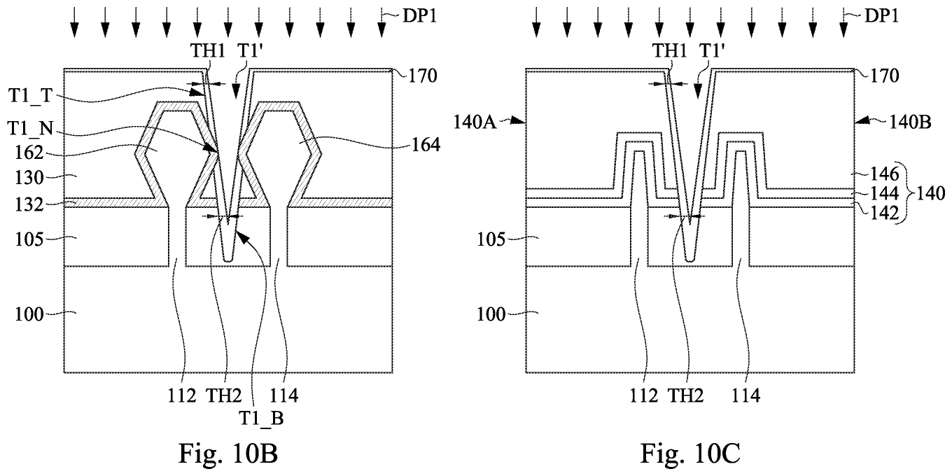

Reference is made to FIGS. 10A to 10C, in which FIG. 10B is a cross-sectional view along line B-B of FIG. 10A, and FIG. 10C is a cross-sectional view along line C-C of FIG. 10A. An atomic layer deposition (ALD) cycle DP1 with plasma treatment is performed to form a dielectric layer 170. The ALD cycle DP1 includes sequentially supplying a first precursor and a second precursor over the substrate 100 (or a process chamber where the substrate 100 is placed), the first precursor may react with the second precursor to form a monolayer of the dielectric layer 170.

In some embodiments, the dielectric layer 170 may be made of silicon nitride. The first precursor may include a silicon-containing precursor, such as silane (SiH₄), disilane (Si₂H₆), trisilane (Si₃H₈), Dichlorosilane (SiH₂Cl₂), another silicon-containing precursor, and/or any combinations thereof. In some embodiments, the second precursor may include nitrogen-containing precursor and hydrogen-containing precursor. For example, the nitrogen-containing precursor may be N₂ or NH₃. The hydrogen-containing gas may be H₂.

With respect to the ALD cycle DP1, the flow rate of the silicon-containing precursor is in a range from about 10 sccm to about 100000 sccm, the flow rate of the nitrogen-containing precursor is in a range from about 100 sccm to about 100000 sccm, and the flow rate of the hydrogen-containing gas is in a range from about 10 sccm to about 10000 sccm. The duration of supplying the first and second precursors (e.g., precursor feed time) is in a range from about 0.1 s to about 100 s. The RF power is in a range from about 10 W to about 1000 W.

In some embodiments, the N-termination species on the top surfaces of the ILD layer 130 and the gate structure 140, and the surfaces of the top portion T1_T of the trench T1 may suppress the precursor absorption, while the NH-termination species on the surfaces of the bottom portion T1_B of the trench T1 will facilitate the precursor absorption. Accordingly, during supplying the first precursor (e.g., silicon-containing precursor), the silicon atoms tend to be absorbed on the surfaces of the bottom portion T1_B of the trench T1 rather than on the top surfaces of the ILD layer 130 and the gate structure 140, and the surfaces of the top portion T1_T of the trench T1. This will result in that the dielectric layer 170 has a higher deposition rate on the surfaces of the bottom portion T1_B of the trench T1 than on the top surfaces of the ILD layer 130 and the gate structure 140, and the surfaces of the top portion T1_T of the trench T1. Accordingly, by performing the first surface treatment ST1 and the second surface treatment ST2, the dielectric layer 170 can be deposited with a bottom-up manner.

The first surface treatment ST1, the second surface treatment ST2, and the ALD cycle DP1 can be collective referred to as a deposition cycle for depositing the dielectric layer 170, in which the deposition cycle can be repeatedly performed to obtain a desired thickness of the dielectric layer 170 along the surface of the trench T1. Referring to the cross-sectional views of FIGS. 7B and 10B, by using the bottom-up deposition as described above, the deposition cycle is performed several times until the trench T1 is changed from a bowling-shape cross-sectional profile to a V-shape cross-sectional profile (e.g., trench T1′ in the dielectric layer 170). The trench T1′ having V-shape cross-sectional profile will facilitate the gap-fill capability and will improve film quality.

With respect to FIGS. 10B and 10C, the dielectric layer 170 has a lateral thickness TH1 at the top portion T1_T of the trench T1, and a lateral thickness TH2 at the bottom portion of the bottom portion T1_B of the trench T1, in which the thickness TH2 is greater than the thickness TH1.

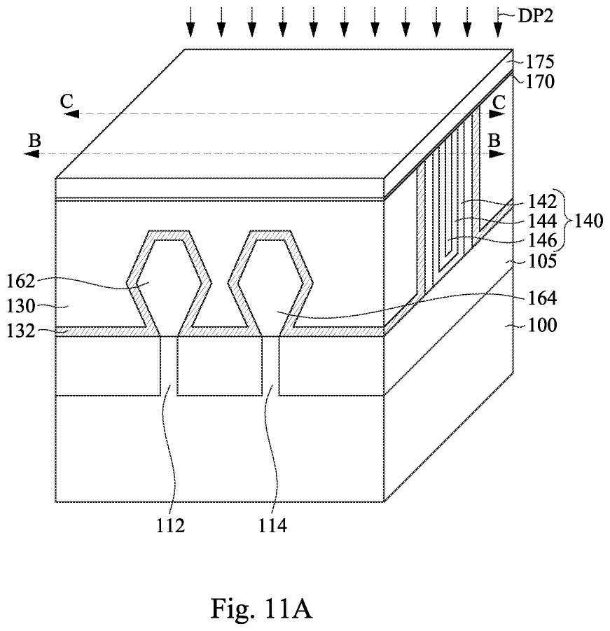

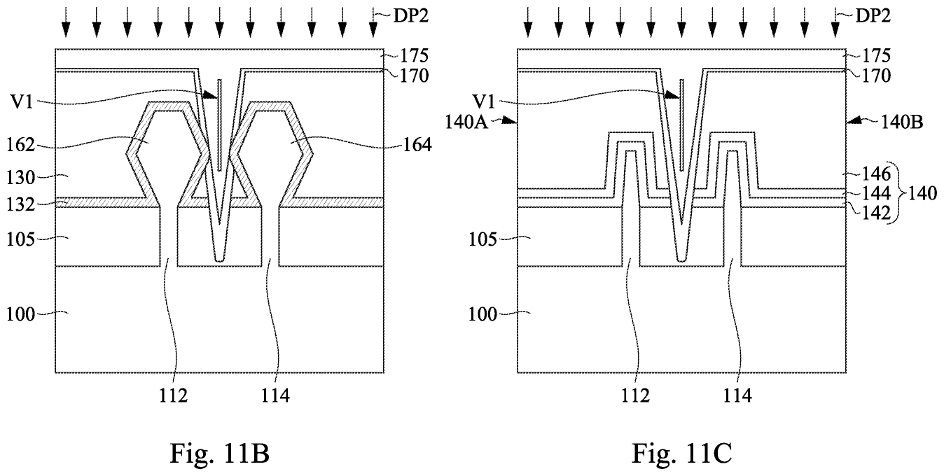

Reference is made to FIGS. 11A to 11C, in which FIG. 11B is a cross-sectional view along line B-B of FIG. 11A, and FIG. 11C is a cross-sectional view along line C-C of FIG. 11A. An atomic layer deposition (ALD) cycle DP2 with plasma treatment is performed to form a dielectric layer 175 over the dielectric layer 170.

The ALD cycle DP2 includes sequentially supplying a first precursor and a second precursor over the substrate 100 (or a process chamber where the substrate 100 is placed), the first precursor may react with the second precursor to form a monolayer of the dielectric layer 175.

In some embodiments, the dielectric layer 175 may be made of silicon nitride, which is the same as the dielectric layer 170. Accordingly, the ALD cycle DP1 and the ALD cycle DP2 may include the same first precursor and the same second precursor. For example, in the ALD cycle DP2, the first precursor may include a silicon-containing precursor, such as silane (SiH₄), disilane (Si₂H₆), trisilane (Si₃H₈), Dichlorosilane (SiH₂Cl₂), another silicon-containing precursor, and/or any combinations thereof. The second precursor may include nitrogen-containing precursor and hydrogen-containing precursor. For example, the nitrogen-containing precursor may be N₂ or NH₃. The hydrogen-containing gas may be H₂. In some other embodiments, the dielectric layer 175 is made of a different material than the dielectric layer 170.

With respect to the ALD cycle DP2, the flow rate of the silicon-containing precursor is in a range from about 10 sccm to about 100000 sccm, the flow rate of the nitrogen-containing precursor is in a range from about 100 sccm to about 100000 sccm, and the flow rate of the hydrogen-containing gas is in a range from about 10 sccm to about 10000 sccm. The duration of supplying the first and second precursors (e.g., precursor feed time) is in a range from about 0.1 s to about 100 s. The RF power is in a range from about 10 W to about 1000 W.

In some embodiments, the flow rate of the first precursor (e.g., the silicon-containing precursor) of the ALD cycle DP2 is greater than the flow rate of the first precursor of the ALD cycle DP1, and the flow rate of the second precursor (e.g., the nitrogen-containing precursor and the hydrogen-containing precursor) of the ALD cycle DP2 is greater than the flow rate of the second precursor of the ALD cycle DP1.

In some embodiments, the ratio of the flow rate of H₂ to the flow rate of N₂ in the ALD cycle DP2 is greater than the ratio of the flow rate of H₂ to the flow rate of N₂ in the ALD cycle DP1. That is, the ALD cycle DP2 has higher high H₂/N₂ gas flow ratio than the ALD cycle DP1. This will result in that the dielectric layer 175 may include higher hydrogen atomic concentration than the dielectric layer 170.

In some embodiments, the precursor feed time of the ALD cycle DP2 is longer than the precursor feed time of the ALD cycle DP1. That is, the duration of supplying the precursors of ALD cycle DP2 is longer than the duration of supplying the precursors of ALD cycle DP1. In some embodiments, the RF power of the ALD cycle DP2 is greater than the RF power of the ALD cycle DP1.

The ALD cycle DP2 can be repeatedly performed to obtain a desired thickness of the dielectric layer 175. In some embodiments, the ALD cycle DP2 is performed several times until the dielectric layer 175 overfills the trench T1′. In some embodiments, the deposition of the dielectric layer 175 is performed without performing the first surface treatment ST1 and the second surface treatment ST2, and thus the dielectric layer 175 may include substantially uniform deposition rate in the trench T1′.

In some embodiments, a void V1 (or air gap) may be formed in the dielectric layer 175. In some embodiments, a width of the void V1 may be less than 1 nm. In some other embodiments, the dielectric layer 175 is formed without void. Moreover, the dielectric layer 170 is formed without void. By using the bottom-up approach to deposited the dielectric layer 170, the trench T1 (see FIGS. 7A to 7C) can be changed from a bowling-shape cross-sectional profile to a V-shape cross-sectional profile (see FIGS. 10A to 10C), the V-shape cross-sectional profile will facilitate the deposition of the dielectric layer 175, and will further reduce the void size in the dielectric layer 175. Accordingly, the device performance will be improved.

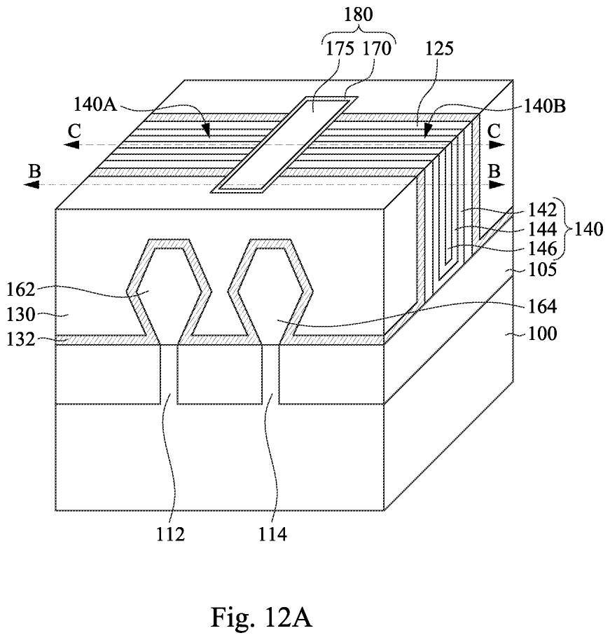

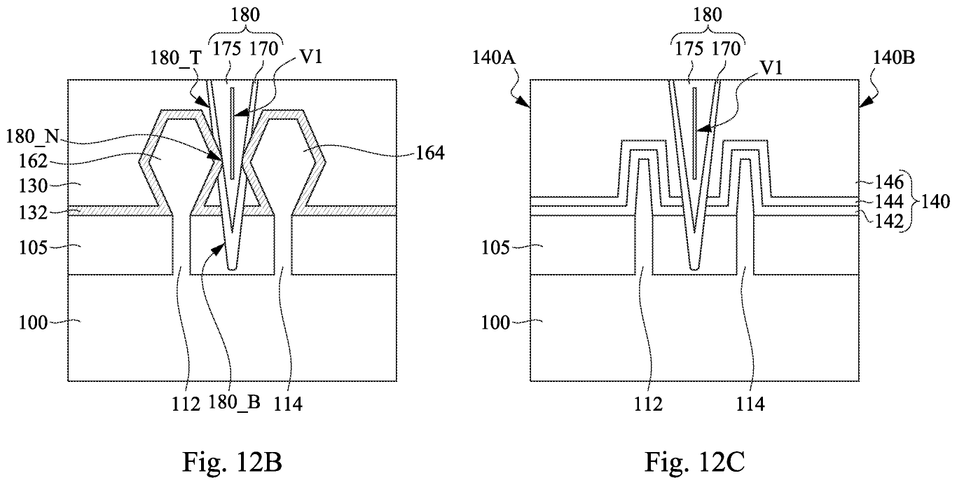

Reference is made to FIGS. 12A to 12C, in which FIG. 12B is a cross-sectional view along line B-B of FIG. 12A, and FIG. 12C is a cross-sectional view along line C-C of FIG. 12A. A CMP process is performed to remove excess materials of the dielectric layers 170 and 175 until the ILD layer 130 and the gate structure 140 are exposed. After the CMP process is completed, the remaining dielectric layers 170 and 175 can be collectively referred to as a dielectric structure 180 or an isolation structure 180. In some embodiments, the isolation structure 180 has opposite sides respectively interfacing a longitudinal end of the gate structure 140A and a longitudinal end of the gate structure 140B. Stated another way, the isolation structure 180 separates the gate structures 140 into separated portions 140A and 140B (or gate structures 140A and 140B).

The dielectric structure 180 includes a dielectric layer 170 and a dielectric layer 175. In the cross-sectional view of FIGS. 12B and 12C, the dielectric layer 170 may cup an underside of the dielectric layer 175. In some embodiments, the dielectric layer 170 has a V-shape cross-sectional profile (or a triangular cross-sectional profile). That is, a width of the dielectric layer 170 may continuously decreases when a distance to the substrate 100 decreases. When in a top view (see FIG. 12A), the dielectric layer 170 may surround the dielectric layer 175. That is, the dielectric layer 170 may cover at least four sides of the dielectric layer 175 in a top view.

In some embodiments, the dielectric structure 180 may inherit the profile of the trench T1 as described in FIGS. 7A to 7C. With respect to the cross-sectional view of FIG. 12B, the dielectric structure 180 in FIG. 12B has a bowling-shape cross-sectional profile. For example, the dielectric structure 180 may include a top portion 180_T and a bottom portion 180_B below the top portion 180_T, in which the top portion 180_T and the bottom portion 180_B are separated by a neck portion 180_N. Here, the neck portion 180_N has a maximal width that is less than the maximal width of the top portion 180_T and the maximal width of the bottom portion 180_B. It is noted that the widths of the top portion 180_T, the bottom portion 180_B, and the neck portion 180_N of the dielectric structure 180 are similar to those described with respect to the widths of the top portion T1_T, the bottom portion T1_B, and the neck portion T1_N of the trench T1, and thus relevant details will not be repeated for brevity.

The neck portion 180_N of the dielectric structure 180 is substantially level to the widest portions of the epitaxial source/drain structures 162 and 164. Stated another way, the neck portion 180_N of the dielectric structure 180 is substantially level to a position where the closest distance between the epitaxial source/drain structures 162 and 164 occurs. Sated another way, the top portion 180_T of the dielectric structure 180 can be referred to as the portion of the dielectric structure 180 above the widest portions of the epitaxial source/drain structures 162 and 164, and the bottom portion 180_B of the dielectric structure 180 can be referred to as the portion of the dielectric structure 180 below the widest portions of the epitaxial source/drain structures 162 and 164.

With respect to the cross-sectional view of FIG. 12C, the dielectric structure 180 in FIG. 12C has a V-shape cross-sectional profile. That is, the width of the dielectric structure 180 in the cross-sectional view of FIG. 12C may continuously decrease from the top end of the dielectric structure 180 toward the bottom end of the dielectric structure 180. In some embodiments, the width variation of the dielectric structure 180 in the cross-sectional view of FIG. 12B is greater than the width variation of the dielectric structure 180 in the cross-sectional view of FIG. 12C.

Based on the above discussion, it can be seen that the present disclosure offers advantages. It is understood, however, that other embodiments may offer additional advantages, and not all advantages are necessarily disclosed herein, and that no particular advantages is required for all embodiments. Embodiments of the present disclosure provide a bi-layer approach to form an isolation structure. A first dielectric layer is deposited in a trench in a bottom-up manner, which will change the trench from a bowling-shape cross-sectional profile to a V-shape cross-sectional profile. A second dielectric layer is then deposited over the first dielectric layer and overfilling the trench. The trench with V-shape cross-sectional profile will facilitate the deposition of the second dielectric layer, which reduces the void size in the second dielectric layer, and will further improve the device performance.

In some embodiments of the present disclosure, a method includes forming a first semiconductor fin and a second semiconductor fin over a substrate; forming a gate structure over the substrate and crossing the first and second semiconductor fins; forming a first source/drain epitaxy structure over the first semiconductor fin and a second source/drain epitaxy structure over the second semiconductor fin, respectively; forming an interlayer dielectric (ILD) layer over the first and second source/drain epitaxy structures; etching the gate structure and the ILD layer to form a trench, the trench being between the first and second source/drain epitaxy structures, in which in a cross-sectional view perpendicular to a lengthwise direction of the first and second semiconductor fins, the trench includes a top portion and a bottom portion separated by a neck portion, the neck portion having a maximal width less than a maximal width of the top portion and a maximal width of the bottom portion; performing a first surface treatment to modify surfaces of the top portion and the bottom portion of the trench to NH-terminated; performing a second surface treatment to modify the surfaces of the top portion of the trench to N-terminated, while leaving the surfaces of the bottom portion of the trench being NH-terminated; and depositing a first dielectric layer in the trench, in which the first dielectric layer has a higher deposition rate on the surfaces of the bottom portion of the trench than on the surfaces of the bottom portion of the trench.

In some embodiments, the first surface treatment includes supplying a first nitrogen containing gas and a hydrogen containing gas over the substrate, and the second surface treatment includes supplying a second nitrogen containing gas over the substrate without using hydrogen containing gas.

In some embodiments, supplying the second nitrogen containing gas is controlled such that the second nitrogen containing gas does not reach the bottom portion of the trench.

In some embodiments, the first surface treatment is performed under a first pressure and the second surface treatment is performed under a second pressure greater than the first pressure.

In some embodiments, a duration of the first surface treatment is longer than a duration of the second surface treatment.

In some embodiments, the method further includes depositing a second dielectric layer over the first dielectric layer and overfilling the trench, in which the second dielectric layer and the first dielectric layer are made of a same material, while the second dielectric layer has a higher hydrogen atomic concentration than the first dielectric layer.

In some embodiments, the neck portion of the trench is substantially level with a widest portion of the first source/drain epitaxy structure.

In some embodiments of the present disclosure, a method includes forming a first semiconductor fin and a second semiconductor fin over a substrate; forming a gate structure over the substrate and crossing the first and second semiconductor fins; forming a first source/drain epitaxy structure over the first semiconductor fin and a second source/drain epitaxy structure over the second semiconductor fin, respectively; forming an interlayer dielectric (ILD) layer over the first and second source/drain epitaxy structures; etching the gate structure to form a trench that breaks the gate structure into discontinuous first and second gate structures, in which the trench has a bowling-shape cross-sectional profile; depositing a first dielectric layer along surfaces of the trench, the trench including a top portion and a bottom portion below the top portion; and depositing a second dielectric layer over the first dielectric layer and overfilling the trench. Depositing the first dielectric layer includes performing a surface modification process such that surfaces of the top portion of the trench and surfaces of the bottom portion of the trench have different termination species; and performing a first deposition cycle by sequentially supplying a first precursor and a second precursor into the trench, in which the surface modification process and the first deposition cycle are repeatedly performed until the trench has a V-shape cross-sectional profile.

In some embodiments, the surface modification process includes performing a first surface treatment by supplying N₂ gas and H₂ gas with plasma treatment; and performing a second surface treatment by supplying N₂ gas with plasma treatment, in which the first surface treatment is performed under a lower pressure than the second surface treatment, such that the surfaces of the top portion of the trench has more N-termination species than the surfaces of the bottom portion of the trench.

In some embodiments, the first surface treatment is performed for a longer duration than the second surface treatment.

In some embodiments, the second surface treatment is performed without using H₂ gas.

In some embodiments, the first dielectric layer has a higher deposition rate at the bottom portion of the trench than at the top portion of the trench.

In some embodiments, the second dielectric layer has a uniform deposition rate at the bottom portion of the trench and at the top portion of the trench.

In some embodiments, the first and second dielectric layers are made of a same material.

In some embodiments, a void is formed in the second dielectric layer, while the first dielectric layer is free of void.

In some embodiments of the present disclosure, a semiconductor device includes a substrate. A first semiconductor fin and a second semiconductor fin are over the substrate. A first gate structure and a second gate structure are over the substrate and cross the first and second semiconductor fins. A first source/drain epitaxy structure is over the first semiconductor fin and a second source/drain epitaxy structure is over the second semiconductor fin, respectively. An isolation structure has opposite sides respectively interfacing a longitudinal end of the first gate structure and a longitudinal end of the second gate structure. The isolation structure includes a first portion, and a second portion over the first portion, in which in a cross-sectional view, the first portion cups an underside of the second portion, and in which the second portion has a higher hydrogen atomic concentration than the first portion.

In some embodiments, the isolation structure has a bowling-shape cross-sectional profile, while the second portion of the isolation structure has a triangular cross-sectional profile.

In some embodiments, in a top view, the first portion covers at least four sides of the second portion.

In some embodiments, a first lateral thickness of the first portion of the isolation structure below a widest portion of the first source/drain epitaxy structure is greater than a second lateral thickness of the first portion of the isolation structure above a widest portion of the first source/drain epitaxy structure.

In some embodiments, the first portion of the isolation structure and the second portion of the isolation structure are made of a same material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor fin and a second semiconductor fin over a substrate;
forming a gate structure over the substrate and crossing the first and second semiconductor fins;
forming a first source/drain epitaxy structure over the first semiconductor fin and a second source/drain epitaxy structure over the second semiconductor fin, respectively;
forming an interlayer dielectric (ILD) layer over the first and second source/drain epitaxy structures;
etching the gate structure and the ILD layer to form a trench, the trench being between the first and second source/drain epitaxy structures, wherein in a cross-sectional view perpendicular to a lengthwise direction of the first and second semiconductor fins, the trench comprises a top portion and a bottom portion separated by a neck portion, the neck portion having a maximal width less than a maximal width of the top portion and a maximal width of the bottom portion;
performing a first surface treatment to modify surfaces of the top portion and the bottom portion of the trench to NH-terminated;
performing a second surface treatment to modify the surfaces of the top portion of the trench to N-terminated, while leaving the surfaces of the bottom portion of the trench being NH-terminated; and
depositing a first dielectric layer in the trench, wherein the first dielectric layer has a higher deposition rate on the surfaces of the bottom portion of the trench than on the surfaces of the bottom portion of the trench.

2. The method of claim 1, wherein,
the first surface treatment comprises supplying a first nitrogen containing gas and a hydrogen containing gas over the substrate, and
the second surface treatment comprises supplying a second nitrogen containing gas over the substrate without using hydrogen containing gas.

3. The method of claim 2, wherein supplying the second nitrogen containing gas is controlled such that the second nitrogen containing gas does not reach the bottom portion of the trench.

4. The method of claim 2, wherein the first surface treatment is performed under a first pressure and the second surface treatment is performed under a second pressure greater than the first pressure.

5. The method of claim 4, wherein a duration of the first surface treatment is longer than a duration of the second surface treatment.

6. The method of claim 1, further comprising depositing a second dielectric layer over the first dielectric layer and overfilling the trench, wherein the second dielectric layer and the first dielectric layer are made of a same material, while the second dielectric layer has a higher hydrogen atomic concentration than the first dielectric layer.

7. The method of claim 1, wherein the neck portion of the trench is substantially level with a widest portion of the first source/drain epitaxy structure.

8. A method, comprising:
forming a first semiconductor fin and a second semiconductor fin over a substrate;
forming a gate structure over the substrate and crossing the first and second semiconductor fins;
forming a first source/drain epitaxy structure over the first semiconductor fin and a second source/drain epitaxy structure over the second semiconductor fin, respectively;
forming an interlayer dielectric (ILD) layer over the first and second source/drain epitaxy structures;
etching the gate structure to form a trench that breaks the gate structure into discontinuous first and second gate structures, wherein the trench has a bowling-shape cross-sectional profile;
depositing a first dielectric layer along surfaces of the trench, the trench comprising a top portion and a bottom portion below the top portion, wherein depositing the first dielectric layer comprises:
performing a surface modification process such that surfaces of the top portion of the trench and surfaces of the bottom portion of the trench have different termination species; and
performing a first deposition cycle by sequentially supplying a first precursor and a second precursor into the trench, wherein the surface modification process and the first deposition cycle are repeatedly performed until the trench has a V-shape cross-sectional profile; and
depositing a second dielectric layer over the first dielectric layer and overfilling the trench.

9. The method of claim 8, wherein the surface modification process comprises:
performing a first surface treatment by supplying N₂ gas and H₂ gas with plasma treatment; and
performing a second surface treatment by supplying N₂ gas with plasma treatment, wherein the first surface treatment is performed under a lower pressure than the second surface treatment, such that the surfaces of the top portion of the trench has more N-termination species than the surfaces of the bottom portion of the trench.

10. The method of claim 9, wherein the first surface treatment is performed for a longer duration than the second surface treatment.

11. The method of claim 9, wherein the second surface treatment is performed without using H₂ gas.

12. The method of claim 8, wherein the first dielectric layer has a higher deposition rate at the bottom portion of the trench than at the top portion of the trench.

13. The method of claim 12, wherein the second dielectric layer has a uniform deposition rate at the bottom portion of the trench and at the top portion of the trench.

14. The method of claim 8, wherein the first and second dielectric layers are made of a same material.

15. The method of claim 8, wherein a void is formed in the second dielectric layer, while the first dielectric layer is free of void.

16. A semiconductor device, comprising:
a substrate;
a first semiconductor fin and a second semiconductor fin over the substrate;
a first gate structure and a second gate structure over the substrate and crossing the first and second semiconductor fins;
a first source/drain epitaxy structure over the first semiconductor fin and a second source/drain epitaxy structure over the second semiconductor fin, respectively; and
an isolation structure having opposite sides respectively interfacing a longitudinal end of the first gate structure and a longitudinal end of the second gate structure, wherein the isolation structure comprises:
a first portion; and
a second portion over the first portion, wherein in a cross-sectional view, the first portion cups an underside of the second portion, and wherein the second portion has a higher hydrogen atomic concentration than the first portion.

17. The semiconductor device of claim 16, wherein the isolation structure has a bowling-shape cross-sectional profile, while the second portion of the isolation structure has a triangular cross-sectional profile.

18. The semiconductor device of claim 16, wherein in a top view, the first portion covers at least four sides of the second portion.

19. The semiconductor device of claim 16, wherein a first lateral thickness of the first portion of the isolation structure below a widest portion of the first source/drain epitaxy structure is greater than a second lateral thickness of the first portion of the isolation structure above a widest portion of the first source/drain epitaxy structure.

20. The semiconductor device of claim 16, wherein the first portion of the isolation structure and the second portion of the isolation structure are made of a same material.
